(19) United States
(12) Patent Application Publication
(10) Pub. No.: US 2007/0197000 A1
(43) Pub. Date: Aug. 23, 2007

(54) Method of manufacturing chip resistors

(76) Inventors: Shiow-Chang Luh, Fongshan City (TW); Chun-Hsiung Kuo, Kaohsiung (TW)

Correspondence Address: HERSHKOVITZ & ASSOCIATES, 2845 DUKE STREET, ALEXANDRIA, VA, 22314, US

(21) Appl. No.: 11/640,373

(22) Filed: Dec. 18, 2006

(30) Foreign Application Priority Data
Feb. 22, 2006 (TW) 095105899

(51) Int. Cl. H01L 21/30

(52) U.S. Cl. 438/458

(57) ABSTRACT

A method of manufacturing chip resistors has steps of cutting grooves in a substrate, forming through holes, defining chip regions, forming main electrodes, forming resistor layers, forming first protective layers, forming stripped protective layers, forming inner electrodes, removing the stripped protective layers, plating outer electrodes and cutting the substrate. The step of cutting grooves on a substrate includes forming multiple parallel grooves on a substrate. The step of forming through holes includes forming multiple through holes between and across two adjacent grooves on the substrate, and each through hole has smooth inner walls. The step of plating outer electrodes includes plating outer electrodes on the inner electrodes by rack plating. The step of cutting the substrate includes cutting the substrate along the grooves to obtain individual chip resistors.

### BACKGROUND OF THE INVENTION

1. Field of the Invention

The present invention relates to a method of manufacturing chip resistors, and more particularly to a method of manufacturing chip resistors that increases the production efficiency and yield.

2. Description of Related Art

Because electronic products are becoming smaller, individual active and passive electronic elements have to become smaller, too. For example, standard chip resistors may be 0.60 mm long, 0.30 mm wide and 0.23 mm deep or 0.40 mm long, 0.20 mm wide and 0.23 mm deep. Smaller elements have smaller tolerances for error.

With reference to FIG. 3, a conventional manufacturing method comprises steps of cutting grooves (21, 22) on a substrate (20), defining chip regions (23), forming main electrodes (24), forming resistor layers (25), forming inner protective layers (26), adjusting resistance, forming outer protective layers (27), dividing the substrate (20) into multiple strips (20′), forming inner electrodes (28), cutting the strips (20′) into multiple chip resistor units (30) and plating outer electrodes (29).

The step of cutting grooves (21, 22) on a substrate (20) comprises mechanically cutting multiple parallel grooves (21) and multiple perpendicular grooves (22) on a substrate (20) with a cutting blade.

The step of defining chip regions (23) comprises defining multiple chip regions (23) between adjacent parallel grooves (21) and perpendicular grooves (22).

The step of forming main electrodes (24) comprises printing and firing metal organic paste on top and bottom surfaces of a substrate (20) to form a pair of main electrodes (24) in each chip region (23). For example, a chip resistor having size of 0.60 mm long, 0.30 mm wide and 0.23 mm deep requires each main electrode (24) to be at least 0.15 mm long.

The step of forming resistor layers (25) comprises printing and firing resistor elements between the two main electrodes (24) in each chip region (23) to form multiple resistor layers (25).

The step of forming inner protective layers (26) comprises printing and firing protective glaze on the resistor layers (25) to form multiple inner protective layers (26).

The step of adjusting resistance comprises carving the inner protective layers (26) and resistor layers (25) with a laser beam to adjust resistance of the resistor layers (25).

The step of forming outer protective layers (27) comprises forming multiple outer protective layers (27) on the inner protective layers (26).

The step of dividing the substrate (20) into multiple strips (20′) comprises cutting the substrate (20) along the perpendicular grooves (22) with a laser beam or a rotating blade to divide the substrate (20) into multiple strips (20′). Each strip (20′) has two cut edges opposite to each other.

The step of forming inner electrodes (28) comprises sputtering inner electrodes (28) respectively on the cut edges of each strip (20′) by vacuum sputtering. The inner electrodes (28) connect the main electrodes (24) respectively on top and bottom surfaces of the substrate (20).

The step of cutting the strips (20′) into multiple chip resistor units (30) comprises cutting the strips (20′) along the parallel grooves (21) into multiple chip resistor units (30).

The step of plating outer electrodes (29) comprises plating outer electrodes (29) on the inner electrodes (28) by barrel plating. Therefore, multiple chip resistors are finished after plating outer electrodes (29) on the chip resistor units (30).

However, the conventional method has the following shortcomings.

1. The substrate (20) easily breaks during the printing and firing processes because the substrate (20) has multiple parallel grooves (21) and perpendicular grooves (22) cut into surfaces of the substrate (20).

2. With further reference to FIG. 4, the inner electrodes (28) may have different thicknesses because the cut edges of each strip (20′) are not smooth when the substrate (20) is divided into multiple strips (20′). Therefore, conductivity of the inner electrodes (28) will vary and adversely influence yield due to inconsistent thickness of the inner electrodes (28).

3. Barrel plating requires a lot of time to plate the outer electrodes (29). Furthermore, barrel plating yield is low because the chip resistor units (30) tend to stick to each because of static electricity generated during barrel plating.

To overcome the shortcomings, the present invention provides a method of manufacturing chip resistors to mitigate or obviate the aforementioned problems.

### SUMMARY OF THE INVENTION

The main objective of the invention is to provide a method of manufacturing chip resistors that increases production efficiency and yield.

A method of manufacturing chip resistors in accordance with the present invention comprises steps of cutting grooves in a substrate, forming through holes, defining chip regions, forming main electrodes, forming resistor layers, forming first protective layers, forming stripped protective layers, forming inner electrodes, removing the stripped protective layers, plating outer electrodes and cutting the substrate. The step of cutting grooves on a substrate comprises forming multiple parallel grooves on a substrate. The step of forming through holes comprises forming multiple through holes between and across two adjacent grooves on the substrate, and each through hole has smooth inner walls. The step of plating outer electrodes comprises plating outer electrodes on the inner electrodes by rack plating. The step of cutting the substrate comprises cutting the substrate along the grooves to obtain individual chip resistors.

Other objectives, advantages and novel features of the invention will become more apparent from the following detailed description when taken in conjunction with the accompanying drawings.

### BRIEF DESCRIPTION OF THE DRAWINGS

FIG. 1A is a flow chart of a method of manufacturing chip resistors in accordance with the present invention;

FIG. 2 is a side view in partial section of a chip resistor manufactured by the method in FIG. 1;

FIG. 3 is a flow chart of a conventional method of manufacturing chip resistors; and

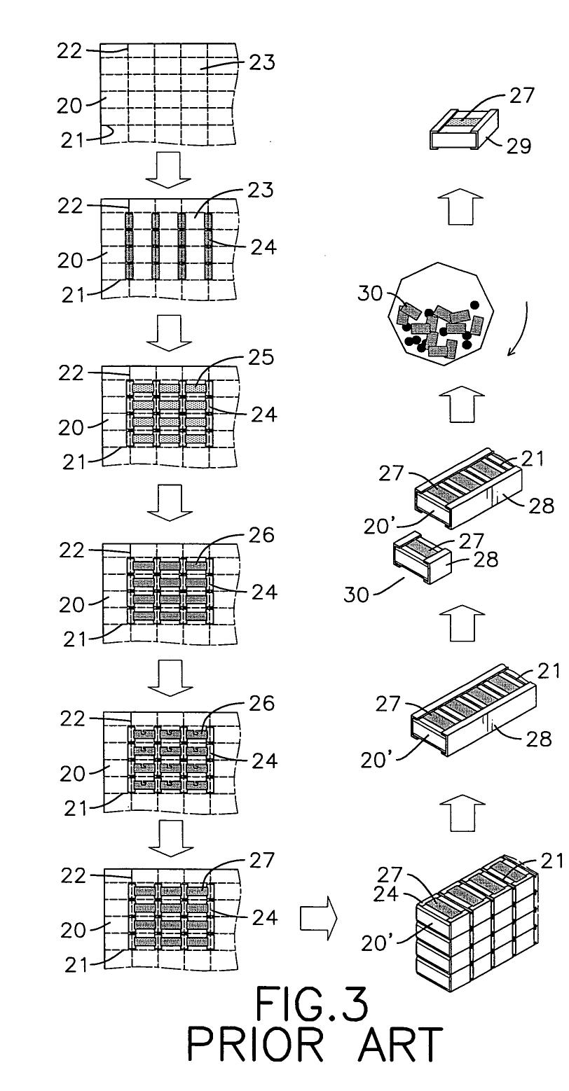

FIG. 4 is a side view in partial section of a chip resistor manufactured by the conventional method in FIG. 3 without showing the inner electrodes and the outer electrodes.

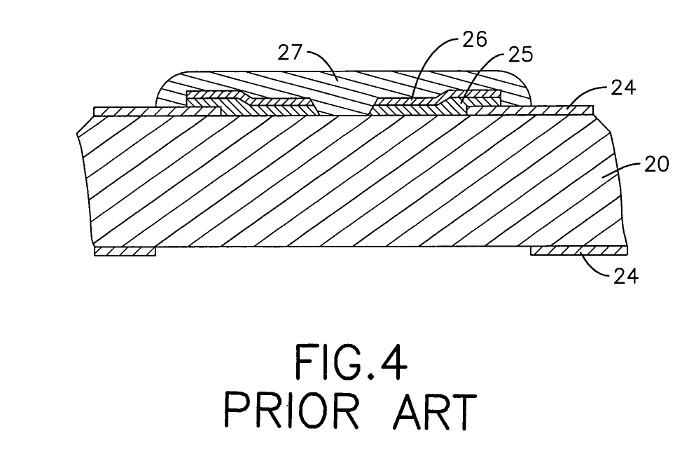

### DETAILED DESCRIPTION OF PREFERRED EMBODIMENT

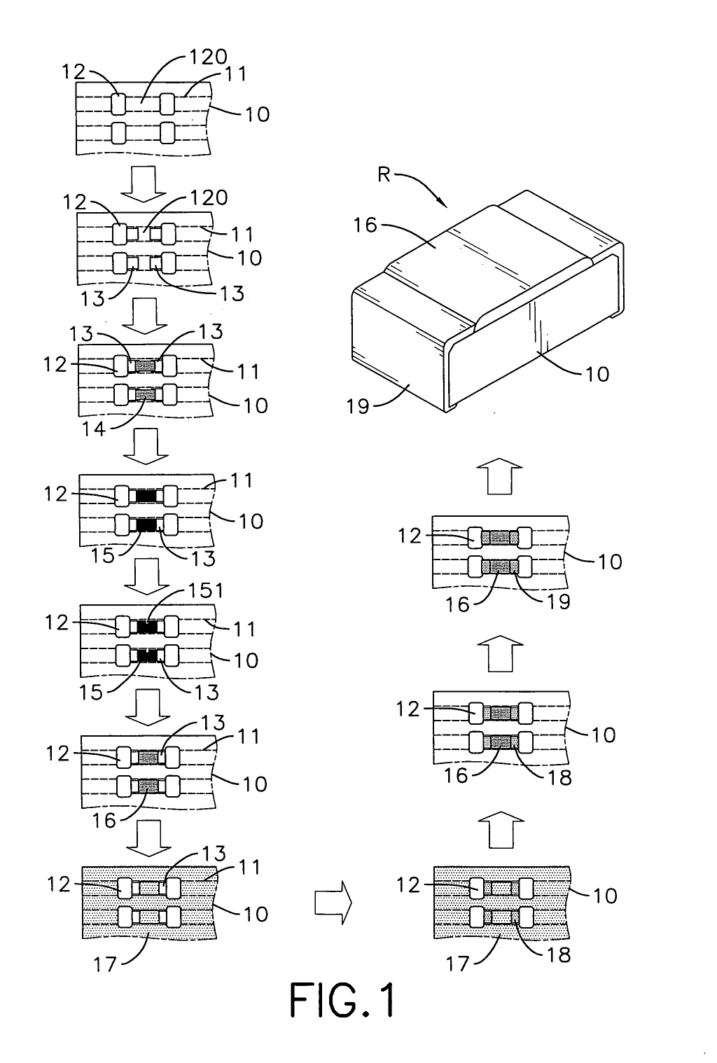

With reference to FIG. 1, a method of manufacturing chip resistors in accordance with the present invention comprises steps of cutting grooves (11) in a substrate (10), forming through holes (12), defining chip regions (120), forming main electrodes (13), forming resistor layers (14), forming first protective layers (15), optionally adjusting resistance, optionally forming second protective layers (16), forming stripped protective layers (17), forming inner electrodes (18), removing the stripped protective layers (17), plating outer electrodes (19) and cutting the substrate (10).

The step of cutting grooves (11) in a substrate (10) may be performed with a blade and comprises cutting multiple grooves (11) parallel to each other in a substrate (10). The substrate (10) has a thickness, a top surface and a bottom surface. Each groove (11) has a depth, and the depth of each groove (11) may not be deeper than half the thickness of the substrate (10).

The step of forming through holes (12) comprises forming multiple through holes (12) through the substrate (10). The through holes (12) are formed between and across two adjacent grooves (11), and each through hole (12) is separated from other through holes (12) and has smooth inner walls.

The step of defining chip regions (120) comprises defining multiple chip regions (120), and each chip region (120) is between adjacent through holes (12) and arranged in a matrix.

The step of forming main electrodes (13) may be performed by printing and firing processes and comprises forming main electrodes (13) on one of the chip regions (120) in pairs on the top and the bottom surfaces of the substrate (10) and respectively on the edges of the through holes (12).

The step of forming resistor layers (14) may be performed by printing and firing processes and comprises forming resistor layers (14) on each chip region (120) electronically connected to the main electrodes (13) and entirely covering the exposed part of the chip region (120). Each resistor layer (14) has a resistance and is electronically connected to the main electrodes (13) in the corresponding chip region (120).

The step of forming first protective layers (15) may be performed by printing and firing processes and comprises forming multiple first protective layers (15) respectively on the chip regions (120) to entirely cover the resistor layers (14).

The step of adjusting resistance comprises carving the first protective layers (15) and resistor layers (14) with a laser beam to adjust resistance of the resistor layers (14).

The step of forming second protective layers (16) may be performed by printing and firing processes and comprises forming multiple second protective layers (16) respectively on and entirely covering the first protective layers (15) to protect the resistor layers (14).

The step of forming stripped protective layers (17) comprises forming multiple stripped protective layers (17) respectively on the top and the bottom surfaces of the substrate (10) between the main electrodes (13).

The step of forming inner electrodes (18) may be performed by vacuum sputtering or vapor deposition and comprises hanging the substrate (10) and plating inner electrodes (18) on the main electrodes (13) and the inner walls of the through holes (12).

The step of removing the stripped protective layers comprises removing the stripped protective layers (17) by ultrasonic cleaning.

The step of plating outer electrodes (19) comprises plating outer electrodes (19) respectively on the inner electrodes (18) by rack plating.

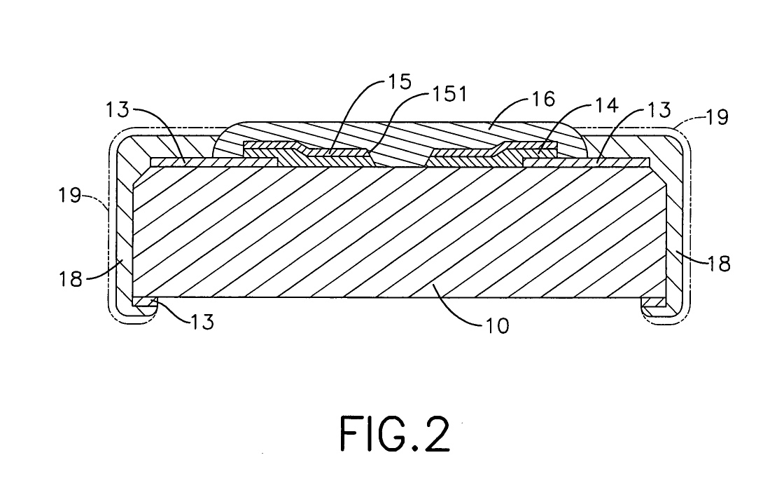

With further reference to FIG. 2, the step of cutting the substrate may be performed by a laser beam or a rotating blade and comprises cutting the substrate (10) along the grooves (11) to obtain multiple chip resistors (R).

Such a method has the following advantages.

1. The substrate (10) is less likely to be broken during printing and firing processes because the method forms fewer grooves (11) does in the substrate (10) than the conventional method and the grooves (11) do not intersect.

2. The inner electrodes (18) are plated on the inner walls of the through holes (12) and are flat because the inner walls are smooth. Therefore, the outer electrodes (19) plated on the inner electrodes (18) are also flat.

3. All chip regions (120) have the same size because each chip region (120) is defined between two through holes (12). Therefore, all chip resistors (R) are the same size.

4. The method in accordance with the present invention is easier than the conventional method because the present method only cuts the substrate (10) once.

5. The method in accordance with the present invention has higher production efficiency and yield because rack plating used to plate the outer electrodes (19) requires less time.

Even though numerous characteristics and advantages of the present invention have been set forth in the foregoing description, together with details of the structure and function of the invention, the disclosure is illustrative only. Changes may be made in detail, especially in matters of arrangement of parts within the principles of the invention to the full extent indicated by the broad general meaning of the terms in which the appended claims are expressed.

What is claimed is:

1. A method of manufacturing chip resistors comprising steps of:
cutting grooves in a substrate comprising cutting multiple grooves parallel to each other in a substrate having a thickness, a top surface and a bottom surface, and each groove has a depth;
forming through holes comprising forming multiple through holes through the substrate between and across each two adjacent grooves in the substrate, and each through hole being separated from other through holes and having smooth inner walls;
defining chip regions comprising defining multiple chip regions, and each chip region being between adjacent through holes and arranged in a matrix;
forming main electrodes comprising forming multiple main electrodes respectively on the top and the bottom surfaces of the substrate on one of the chip regions in pairs and respectively on the edges of the through holes;
forming resistor layers comprising forming resistor layers on each chip region electronically connected to the main electrodes and entirely covering the exposed part of the chip region;
forming first protective layers comprising forming multiple first protective layers respectively on the chip regions to entirely cover the resistor layers;
forming stripped protective layers comprising forming multiple stripped protective layers respectively on the top and the bottom surfaces of the substrate between the main electrodes;
forming inner electrodes comprising hanging the substrate and plating inner electrodes on the main electrodes and the inner walls of the through holes;
removing the stripped protective layers comprising removing the stripped protective layers by ultrasonic cleaning;
plating outer electrodes comprising plating outer electrodes respectively on the inner electrodes by rack plating; and
cutting the substrate comprising cutting the substrate along the grooves to obtain multiple chip resistors.

2. The method as claimed in claim 1, wherein after the step of forming first protective layers the method further comprises steps of
adjusting resistance comprising carving the first protective layers and resistor layers with a laser beam to adjust resistance of the resistor layers; and
forming second protective layers comprising forming multiple second protective layers respectively on and entirely covering the first protective layers.

3. The method as claimed in claim 1, wherein the depth of each groove is not deeper than half the thickness of the substrate.

4. The method as claimed in claim 1, wherein the steps of forming main electrodes, forming resistor layers and forming first protective layers are performed by printing and firing processes.

5. The method as claimed in claim 1, wherein the step of forming inner electrodes is performed by vacuum sputtering.

6. The method as claimed in claim 1, wherein the step of forming inner electrodes is performed by vapor deposition.

7. The method as claimed in claim 1, wherein the step of cutting the substrate is performed by a laser beam.

8. The method as claimed in claim 1, wherein the step of cutting the substrate is performed by a rotating blade.

9. The method as claimed in claim 2, wherein the depth of each groove is not deeper than half depth of the substrate.

10. The method as claimed in claim 2, wherein the steps of forming main electrodes, forming resistor layers, forming first protective layers and forming second protective layers are performed by printing and firing processes.

11. The method as claimed in claim 2, wherein the step of forming inner electrodes is performed by vacuum sputtering.

12. The method as claimed in claim 2, wherein the step of forming inner electrodes is performed by vapor deposition.

13. The method as claimed in claim 2, wherein the step of cutting the substrate is performed by a laser beam.

14. The method as claimed in claim 2, wherein the step of cutting the substrate is performed by a rotating blade.
